(19) United States
(12) Patent Application Publication
(10) Pub. No.: US 2017/0358357 A1
(43) Pub. Date: Dec. 14, 2017

(54) MEMORY DEVICE AND OPERATING METHOD THEREOF

(71) Applicant: MACRONIX INTERNATIONAL CO., LTD., Hsinchu (TW)

(72) Inventors: Chun-Hsiung Hung, Hsinchu City (TW); Kuen-Long Chang, Taipei City (TW); Ken-Hui Chen, Hsinchu City (TW); Su-Chueh Lo, Miaoli City (TW); Ming-Chih Hsieh, Taipei City (TW)

(21) Appl. No.: 15/390,823

(22) Filed: Dec. 27, 2016

Related U.S. Application Data
(60) Provisional application No. 62/349,678, filed on Jun. 14, 2016.

(51) Int. Cl. G11C 16/08; G11C 16/14

(52) U.S. Cl. CPC G11C 16/08; G11C 16/14

(57) ABSTRACT

A memory device and an operating method thereof are provided. The memory device includes a first memory array, a first row decoder, a first column decoder, a second memory array, a second row decoder and a second column decoder. The first memory array and the second memory array are different type memories and formed in a single memory die of a wafer.

This application claims the benefit of the U.S. provisional application Ser. No. 62/349,678, filed Jun. 14, 2016, the subject matter of which is incorporated herein by reference.

### TECHNICAL FIELD

The disclosure relates in general to a memory device and an operating method thereof, and more particularly to a memory device including two memory arrays and an operating method thereof.

### BACKGROUND

Along with the development of memory, several kinds of memory are invented. For example, DRAM, Flash memory, EEPROM, SRAM and ROM are widely used in daily life. Those memories have different characteristics. The advantage of DRAM is its structural simplicity, compared to four or six transistors in SRAM. This allows DRAM to reach very high densities. One key disadvantage of Flash memory is that the erasing unit of the Flash memory is quiet large, compared to EEPROM. EEPROM is used to store relatively small amounts of data and allowed individual bytes to be erased and reprogrammed.

One kind of the memories is selected to be used in an electric device for achieving a particular storage purpose. The data management is limited and is not flexible due to the particular characteristic of the selected memory.

### SUMMARY

The disclosure is directed to a memory device and an operating method thereof. The memory device includes two memory arrays which are different type memories and formed in a single memory die of a wafer. Therefore, the memory device can achieve both of the advantages of the two memory arrays.

According to one embodiment, a memory device is provided. The memory device includes a first memory array, a first row decoder, a first column decoder, a second memory array, a second row decoder and a second column decoder. The first memory array and the second memory array are different type memories and formed in a single memory die of a wafer. The first row decoder is connected to the first memory array. The first column decoder is connected to the first memory array. The first row decoder and the first column decoder are used for accessing the first memory array. The second row decoder is connected to the second memory array. The second column decoder is connected to the second memory array. The second row decoder is different from the first row decoder. The second column decoder is different from the first column decoder. The second row decoder and the second column decoder are used for accessing the second memory array.

According to another embodiment, an operating method of a memory device is provided. The memory device includes a first memory array, a first row decoder, a first column decoder, a second memory array, a second row decoder and a second column decoder. The first memory array and the second memory array are different type memories and formed in a single memory die of a wafer. The first row decoder is connected to the first memory array. The first column decoder is connected to the first memory array. The first row decoder and the first column decoder are used for accessing the first memory array. The second row decoder is connected to the second memory array. The second column decoder is connected to the second memory array. The second row decoder is different from the first row decoder. The second column decoder is different from the first column decoder. The second row decoder and the second column decoder are used for accessing the second memory array. The operating method includes the following steps: The first memory array is programmed, erased or read. A programming unit of the first memory array is less than an erasing unit of the first memory array. The second memory array is written, erased or read. Each cell of the second memory array is written to be a program state or an erase state.

### BRIEF DESCRIPTION OF THE DRAWINGS

FIG. 1 shows a wafer.

FIGS. 2A to 2D show an example of an unidirectional operation of the first memory array.

FIGS. 3A to 3C show an example of a bidirectional operation of the second memory array.

FIG. 4 shows a memory device.

FIG. 5 shows a first memory array and a second memory array.

FIG. 6A illustrates “read while write” according to one embodiment.

FIG. 6B illustrates “read while write” according to another embodiment.

FIG. 6C illustrates “write while write” according to one embodiment.

FIG. 7A illustrates “suspend and resume” according to one embodiment.

FIG. 7B illustrates “suspend and resume” according to another embodiment.

FIG. 8 illustrates a logical address region of the memory device.

In the following detailed description, for purposes of explanation, numerous specific details are set forth in order to provide a thorough understanding of the disclosed embodiments. It will be apparent. however, that one or more embodiments may be practiced without these specific details. In other instances, well-known structures and devices are schematically shown in order to simplify the drawing.

### DETAILED DESCRIPTION

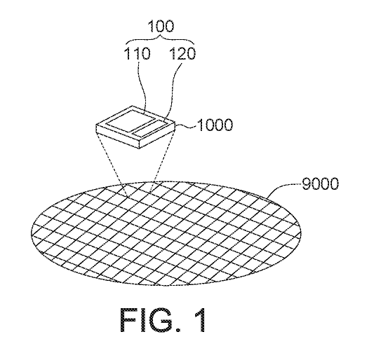

Please refer to FIG. 1, which shows a wafer 9000. The wafer 9000 includes a plurality of memory dies 1000. A memory device 100 includes a first memory array 110 and a second memory array 120 which are formed in one single memory die 1000 of the wafer 9000. The first memory array 110 and the second memory array 120 are different type memories. For example, the first memory array 110 is a unidirectional-rewriteable non-volatile memory and the second memory array 120 is a bidirectional-rewriteable non-volatile memory.

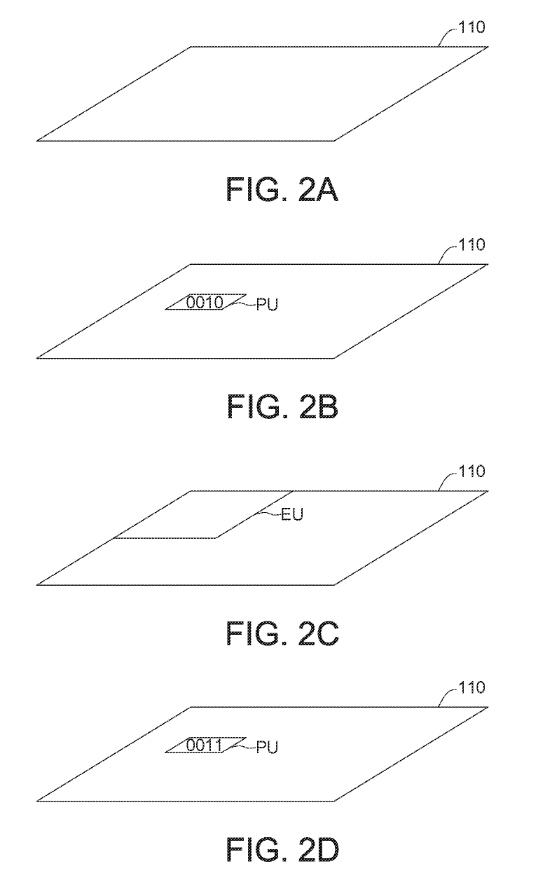

Each cell of the first memory array 110 can be programmed to be a program state. A programming unit of the first memory array 110 is a bit, a byte, a word or a page. An erasing unit of the first memory array 110 is a sector, which is larger than the programming unit. For example, the first memory array 110 may be programmed for one page, but the first memory array 110 must be erased for one sector which includes several pages. Please refer to FIGS. 2A to 2D, which show an example of an unidirectional operation of the first memory array 110. Referring to FIGS. 2A to 2B, one programming unit PU can be programmed to be “0010”. If “0010” is needed to be changed replaced by “0011”, then the first memory array 110 is needed to be erased first. Referring to FIGS. 2B to 20, the first memory array 110 is erased for one erasing unit EU which is larger than the programming unit PU. Then, referring to FIGS. 20 to 20, the programming unit PU corresponding with the previously recorded “0010” is programmed to be “0011.” That is to say, the programming operation of the first memory array 110 is unidirectional for the programming unit. In one embodiment, the first memory array 110 may be a flash memory.

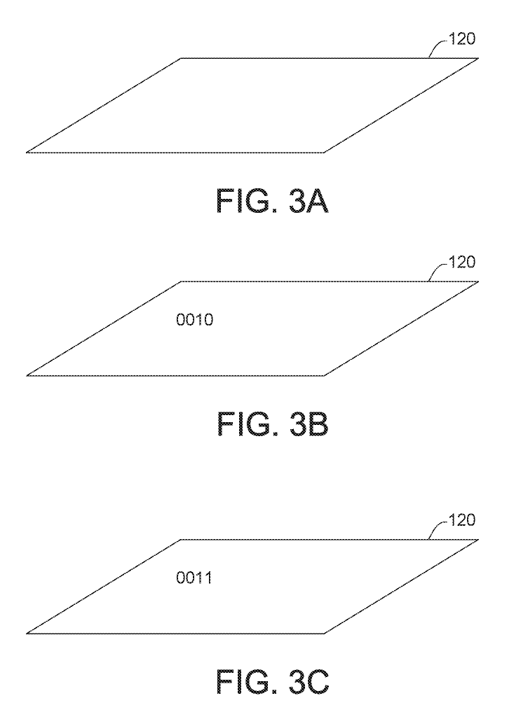

Each cell of the second memory array 120 can be written to be a program state or an erase state. One bit of the second memory array 120 may be written to be the program state, and this bit of the second memory array 120 may be individually written to be the erase state from the program state. Please refer to FIGS. 3A to 3C, which show an example of a bidirectional operation of the second memory array 120. Referring to FIGS. 3A to 3B, four bits can be written be “0010”. If “0010” is needed to be replaced by “0011”, then only the fourth bit is needed to be wrote again. Referring to FIGS. 3B to 3C, the fourth bit of the previously recorded “0010” is written to be “1.” That is to say, the writing operation of the second memory array 120 is bidirectional. In one embodiment, the second memory array 120 may be an Electrically-Erasable Programmable Read-Only Memory (EEPROM).

The first memory array 110 and the second memory array 120 have different advantages. For example, the manufacturing cost of the first memory array 110 is low. Some data which is sector-rewritten unit can be stored in the first memory array 110, and some data which is bit-rewritten unit can be stored in the second memory array 120. Therefore, the memory device 100 can achieve both of low manufacturing cost and high rewriting speed.

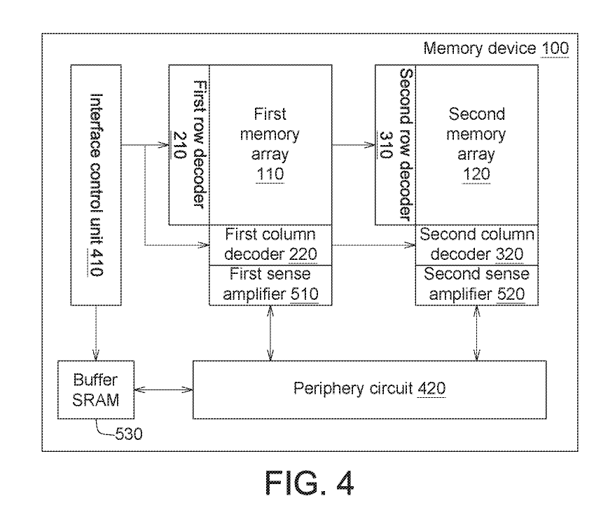

Please refer to FIG. 4, which shows a memory device 100. The memory device 100 includes the first memory array 110, the second memory array 120, a first row decoder 210, a first column decoder 220, a second row decoder 310, a second column decoder 320, an interface control unit 410, a periphery circuit 420, a first sense amplifier 510, a second sense amplifier 520 and a buffer SRAM 530.

The first row decoder 210 is connected to the first memory array 110. The first column decoder 220 is connected to the first memory array 110. The first row decoder 210 and the first column decoder 220 are used for accessing the first memory array 110.

The second row decoder 310 is connected to the second memory array 120. The second column decoder 320 is connected to the second memory array 120. The second row decoder 310 and the second column decoder 320 are used for accessing the second memory array 120.

The first row decoder 210 and the second row decoder 310 are different. The first column decoder 220 and the second column decoder 320 are different. The accessing system of the first memory array 110 and the accessing system of the second memory array 120 are different. Accessing the first memory array 110 and accessing the second memory array 120 are independently performed.

The interface control unit 410 is used to control the first row decoder 210, the first column decoder 220, the second row decoder 310 and the second column decoder 320. The periphery circuit 420 includes a state machine, a high voltage generator and an output buffer. Each of the first sense amplifier 510 and second sense amplifier 520 is a row buffer which stores the data to be outputted.

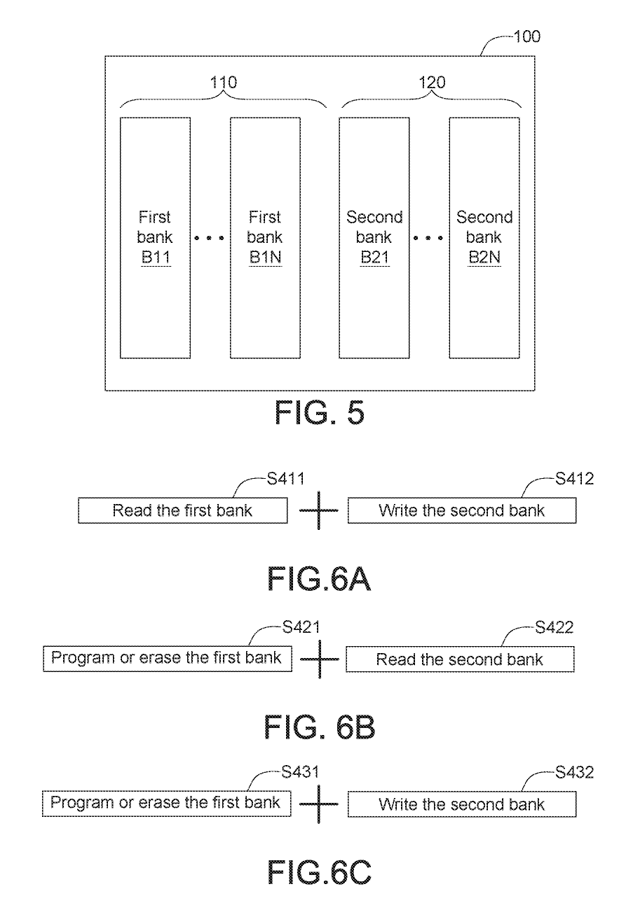

Refer to FIG. 5, which shows the first memory array 110 and the second memory array 120. The first memory array 110 includes at least one first bank, such as a plurality of first banks B11 to B1N, and the second memory array 120 includes at least one second bank, such as a plurality of second banks B21 to B2N. Because accessing the first memory array 110 and accessing the second memory array 120 are independently performed, the operation of one of the first banks B11 to B1N and the operation of one of the second banks B21 to B2N can be performed simultaneously for saving the operating time. This embodiment can be implemented by “read while write” or “write while write.”

Refer to FIG. 6A, which illustrates “read while write” according to one embodiment. In step S411, one of the first banks B11 to B1N is read. In step S412, one of the second banks B21 to B2N is written. Because the reading operation of the first banks B11 to B1N and the writing operation of the second banks B21 to B2N do not interfere with each other, the step S411 and step S412 can be performed simultaneously. That is to say, one of the first banks B11 to B1N is read while one of the second banks B21 to B2N is written simultaneously.

Refer to FIG. 6B, which illustrates “read while write” according to another embodiment. In step S421, one of the first banks B11 to B1N is programmed or erased. In step S422, one of the second banks B21 to B2N is read. Because the programming operation (or the erasing operation) of the first banks B11 to B1N and the reading operation of the second banks B21 to B2N do not interfere with each other, the step S421 and step S422 can be performed simultaneously. That is to say, one of the second banks B21 to B2N is read while one of the first banks B11 to B1N is programmed or erased simultaneously.

Refer to FIG. 6C, which illustrates “write while write” according to one embodiment. In step S431, one of the first banks B11 to B1N is programmed or erased. In step S432, one of the second banks B21 to B2N is written. Because the programming operation (or the erasing operation) of the first banks B11 to B1N and the writing operation of the second banks B21 to B2N do not interfere with each other, the step S431 and step S432 can be performed simultaneously. That is to say, one of the first banks B11 to B1N is programmed or erased while one of the second banks B21 to B2N is written simultaneously.

Further, because accessing the first memory array 110 and accessing the second memory array 120 are independently performed, the operation of one of the first banks B11 to B1N can be suspended to execute the operation of one of the second banks B21 to B2N, and then the operation of one of the first banks B11 to B1N can be resumed; the operation of one of the second banks B21 to B2N can be suspended to execute the operation of one of the first banks B11 to B1N, and then the operation of one of the second banks B21 to B2N can be resumed. Therefore, the operations of the memory device 100 are more flexible. This embodiment can be called as “suspend and resume.”

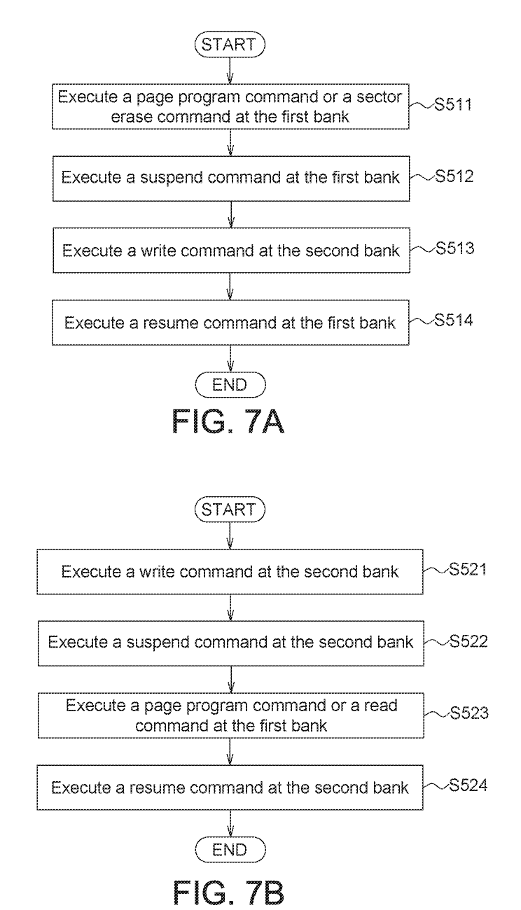

Refer to FIG. 7A, which illustrates “suspend and resume” according to one embodiment. In step S511, a page program command or a sector erase command is executed at one of the first banks B11 to B1N.

In step S512, a suspend command is executed at that one of the first banks B11 to B1N whose programming operation or erasing operation is executing. At this step, the erasing operation may be unfinished.

In step S513, a write command is executed at one of the second banks B21 to B2N.

In step S514, after the writing operation in step S513 is finished, a resume command is executed at that one of the first banks B11 to B1N whose programming operation or erasing operation is suspended.

During this process, because the programming operation (or the erasing operation) of the first banks B11 to B1N and the writing operation of the second banks B21 to B2N do not interfere with each other, the programming operation (or the erasing operation) of the first banks B11 to B1N can be suspended to perform the writing operation of the second banks B21 to B2N, and then the programming operation (or the erasing operation) of the first banks B11 to B1N can be resumed latter.

Refer to FIG. 7B, which illustrates “suspend and resume” according to another embodiment. In step S521, a write command is executed at one of the second banks B21 to B2N.

In step S522, a suspend command is executed at one of the second banks B21 to B2N whose writing operation is executing. At this step, the writing operation may be unfinished.

In step S523, a page program command or a read command is executed at one of the first banks B11 to B1N.

In step S524, after the programming operation (or the reading operation) in step S523 is finished, a resume command is execute at that one of the second banks B21 to B2N whose writing operation is suspended.

During this process, because the writing operation of the second banks B21 to B2N and the programming operation (or the reading operation) of the first banks B11 to B1N do not interfere with each other, the writing operation of one of the second banks B21 to B2N can be suspended to perform the programming operation (or the reading operation) of one of the first banks B11 to B1N, and then the writing operation can be resumed latter.

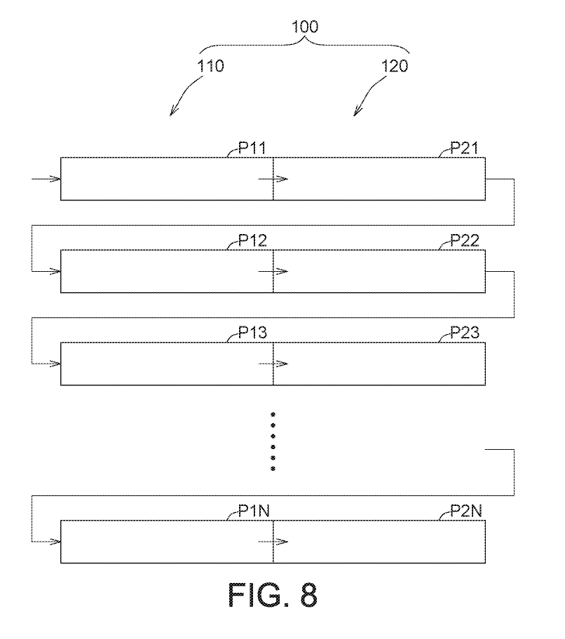

Refer to FIG. 8, which illustrates a logical address region of the memory device 100. The first memory array 110 includes a plurality of first pages P11, P12, P13, . . . , P1N. The second memory array 120 includes a plurality of second pages P21, P22, P23, . . . , P2N. The first pages P11 to P1N and the second pages P21 to P2N are interleaved in the logical address region. For example, the first page P11, the second page P21, the first page P12, the second page P22, the first page P13, the second page P23, . . . , the first page P1N, and the second page P2N are arranged sequentially in the logical address region. In another embodiment, the second page P21, the first page P11, the second page P22, the first page P12, the second page P23, the first page P13, . . . , the second page P2N and the first page P1N are arranged sequentially in the logical address region. In another embodiment, the first pages P11 to P1N and the second pages P21 to P2N may be non-interleaved in the logical address region. For example, the first page P11, the first page P12, the first page P13, . . . , and the first page P1N are continuously arranged in one part of the logical address region. The second page P21, the second page P22, the second page P23, . . . , and the second page P2N are continuously arranged in another part of the logical address region.

According to those embodiments, the first memory array 110 and the second memory array 120 are formed in one single memory die of the wafer 9000, such that the memory device 100 can achieve both of low manufacturing cost and high rewriting speed. Further, in “read while write”, the operation of one of the first banks B11 to B1N and the operation of one of the second banks B21 to B2N can be performed simultaneously for saving the operating time. Moreover, in “suspend and resume”, the operation can be suspended and then be resumed; such that the operations of the memory device 100 are more flexible.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A memory device, comprising:
a first memory array;
a first row decoder connected to the first memory array;
a first column decoder connected to the first memory array, wherein the first row decoder and the first column decoder are used for accessing the first memory array;
a second memory array, wherein the first memory array and the second memory array are different type memories and formed in a single memory die of a wafer;
a second row decoder connected to the second memory array; and
a second column decoder connected to the second memory array, wherein the second row decoder is different from the first row decoder, the second column decoder is different from the first column decoder, the second row decoder and the second column decoder are used for accessing the second memory array, the first memory array includes a plurality of first pages, the second memory array includes a plurality of second pages, and the first pages and the second pages are interleaved in a logical address region.

2. The memory device according to claim 1, wherein the first memory array is a unidirectional-rewriteable non-volatile memory, and a programming unit of the first memory array is less than an erasing unit of the first memory array.

3. The memory device according to claim 2, wherein the programming unit of the first memory array is a bit, a byte, a word or a page, and the erasing unit of the first memory array is a sector.

4. The memory device according to claim 1, wherein the second memory array is a bidirectional-rewriteable non-volatile memory and each cell of the second memory array is written to be a program state or an erase state.

5. The memory device according to claim 1, wherein the first memory array includes at least one first bank, and the second memory array includes at least one second bank, the first bank is read while the second bank is written simultaneously.

6. The memory device according to claim 1, wherein the first memory array includes at least one first bank, and the second memory array includes at least one second bank, the second bank is read while the first bank is programmed or erased simultaneously.

7. The memory device according to claim 1, wherein the first memory array includes at least one first bank, and the second memory array includes at least one second bank, the first bank is programmed or erased while the second bank is written simultaneously.

8. The memory device according to claim 1, wherein the first memory array includes at least one first bank, and the second memory array includes at least one second bank, erasing or programming the first bank is suspended and then writing the second bank is performed.

9. The memory device according to claim 1, wherein the first memory array includes at least one first bank, and the second memory array includes at least one second bank, writing the second bank is suspended and then programming or reading the first bank is performed.

10-11. (canceled)

12. An operating method of a memory device, wherein the memory device includes a first memory array, a first row decoder, a first column decoder, a second memory array, a second row decoder and a second column decoder, the first memory array and the second memory array are different type memories and formed in a single memory die of a wafer, the first row decoder is connected to the first memory array, the first column decoder is connected to the first memory array, the first row decoder and the first column decoder are used for accessing the first memory array, the second row decoder is connected to the second memory array, the second column decoder is connected to the second memory array, the second row decoder is different from the first row decoder, the second column decoder is different from the first column decoder, the second row decoder and the second column decoder are used for accessing the second memory array, and the operating method comprises:
programming, erasing or reading the first memory array, wherein a programming unit of the first memory array is less than an erasing unit of the first memory array; and
writing, erasing or reading the second memory array, wherein each cell of the second memory array is written to be a program or an erase state;
wherein the first memory array includes a plurality of first pages, the second memory array includes a plurality of second pages, the first pages and the second pages are interleaved in a logical address region.

13. The operating method of the memory device according to claim 12, wherein the programming unit of the first memory array is a bit, a byte, a word or a page, and the erasing unit of the first memory array is a sector.

14. The operating method of the memory device according to claim 12, wherein the first memory array includes at least one first bank, and the second memory array includes at least one second bank, the first bank is read while the second bank is written simultaneously.

15. The operating method of the memory device according to claim 12, wherein the first memory array includes at least one first bank, and the second memory array includes at least one second bank, the second bank is read while the first bank is programmed or erased simultaneously.

16. The operating method of the memory device according to claim 12, wherein the first memory array includes at least one first bank, and the second memory array includes at least one second bank, the first bank is programmed or erased while the second bank is written simultaneously.

17. The operating method of the memory device according to claim 12, wherein the first memory array includes at least one first bank, and the second memory array includes at least one second bank, erasing or programming the first bank is suspended and then writing the second bank is performed.

18. The operating method of the memory device according to claim 12, wherein the first memory array includes at least one first bank, and the second memory array includes at least one second bank, writing the second bank is suspended and then programming or reading the first bank is performed.

19-20. (canceled)
